(19) United States
(12) Patent Application Publication
(10) Pub. No.: US 2016/0219742 A1
(43) Pub. Date: Jul. 28, 2016

(54) A BUILDING MANAGEMENT RACK SYSTEM

(71) Applicant: SCHNEIDER ELECTRIC IT CORPORATION, West Kingston, RI (US)

(72) Inventor: Gregory Rutledge, Haverhill, MA (US)

(21) Appl. No.: 14/917,385

(22) PCT Filed: Sep. 9, 2013
(86) PCT No.: PCT/US13/58749

§ 371 Date: Mar. 8, 2016

(51) Int. Cl. H05K 7/14

(52) U.S. Cl. CPC H05K 7/14

(57) ABSTRACT

Disclosed herein are aspects and embodiments of a building management system. In one example, a building management system includes a building system controller disposed within a drawer enclosure having dimensions providing for the drawer enclosure to be mounted in a network equipment rack having an industry standard configuration.

### BACKGROUND

1. Technical Field

Aspects and embodiments disclosed herein relate to building management systems and to methods and apparatus for mounting building management systems.

2. Discussion of Related Art

A building management system (BMS) is a computer-based control system installed in a building and configured to monitor and control various forms of mechanical and electrical equipment in the building. Types of systems which may be monitored and controlled by a BMS include, for example, heating, ventilation, and air conditioning (HVAC) systems, lighting systems, power systems, fire control systems, and security systems. Building management systems are most commonly implemented in commercial buildings, for example, office buildings, which include extensive mechanical, electrical, and plumbing systems. In addition to monitoring and controlling the internal environment of a building, BMS systems are sometimes linked to access control systems and elevators. In one example, if a fire is detected a BMS could shut off dampers in a ventilation system of a building to stop smoke from spreading and send all elevators in the building to the ground floor and park them to prevent people from using them to enter dangerous areas of the building.

The electrical components of a BMS are typically mounted within a custom made enclosure disposed on a wall of, for example, a utility room or closet of a building during construction of the building. Because of this, BMS systems are often perceived as mechanical items. This perception can cause the location and provision of scalability for a BMS to be an afterthought in the planning stages of the construction of a building. BMS enclosures are typically not designed to be scalable. Thus, if a building owner desires to upgrade or expand a previously installed BMS, for example, by adding an additional controller for an additional building system, a new wall mounted enclosure must be purchased and installed where wall space can be found. If extra wall space proximate the original BMS installation was not previously allotted, the vendor of the BMS system and building owner must work together to find alternative open wall space. In some instances wall space for the BMS expansion may not be proximate the original BMS installation, which may result in BMS components being located in numerous different areas, which may render servicing or troubleshooting of the BMS confusing or troublesome. Today, with industry standard BMS implementations, relocating the BMS controllers, for example, to consolidate various BMS controllers in a single location, is nearly impossible without significant time and capital investments.

### SUMMARY

In accordance with an aspect of the present disclosure, there is provided a building management system. The building management system comprises a building system controller disposed within a drawer enclosure having dimensions providing for the drawer enclosure to be mounted in a network equipment rack having an industry standard configuration.

In some embodiments, the building management system further comprises an input/output module disposed within the drawer enclosure, the input/output module configured to transfer data from a building system to the building system controller and to transfer commands from the building system controller to the building system.

In some embodiments, the drawer enclosure is mounted in the network equipment rack.

In some embodiments, the input/output module is in communication with the building system through a network interface of a piece of network technology equipment mounted in the network equipment rack in an enclosure distinct from the drawer enclosure.

In some embodiments, the building management system further comprises a second building system controlled disposed within the drawer enclosure.

In some embodiments, the building management system further comprises a second input/output module disposed within the drawer enclosure, the second input/output module configured to transfer data from a second building system to the second building system controller and to transfer commands from the second building system controller to the second building system.

In some embodiments, the building management system further comprises a building management system power supply configured to provide power to the building system controller, the building management system power supply disposed in a power supply drawer mounted in the network equipment rack.

In some embodiments, the building management system further comprises a second building management system power supply configured to provide power to a second building system controller disposed within the drawer enclosure, the second building management system power supply disposed in the power supply drawer mounted in the network equipment rack.

In some embodiments, the building management system further comprises an uninterruptible power supply configured to provide power to the building management system power supply, the uninterruptible power supply mounted in the network equipment rack.

In some embodiments, the building management system further comprises an automatic transfer switch configured to provide power to the building management system power supply, the automatic transfer switch mounted in the network equipment rack.

In some embodiments, the building management system further comprises a front end workstation mounted in the network equipment rack, the front end workstation configured to record data provided by the building system controller and to perform analysis on the data.

In some embodiments, the drawer enclosure includes a flexible cable management raceway having a first end secured to a rear wall of the drawer enclosure and a second end secured to a movable internal portion of the drawer.

In some embodiments, the drawer enclosure includes one or more apertures defined in a wall of the drawer enclosure.

In some embodiments, the network equipment rack is disposed in an information technology data center including one or more building systems which the building system controller is configured to control and monitor.

In some embodiments, the one or more building systems are selected from the group consisting of a lighting system, a cooling system, an access control system, and a fire control system.

In accordance with another aspect of the present disclosure, there is provided a method of assembling a building management system. The method comprises mounting a building system controller within a drawer enclosure having dimensions providing for the drawer enclosure to be mounted in a network equipment rack having industry standard dimensions, mounting the drawer enclosure on the network equipment rack, mounting a building management system power supply on the network equipment rack, electrically coupling the building management system power supply to the building system controller, and providing a communication link between the building system controller and a building system which the building system controller is configured to monitor and control.

In some embodiments, providing the communication link between the building system controller and the building system comprises providing communication between an input/output module disposed in the drawer enclosure, the building system controller, and the building system.

In some embodiments, providing the communication link between the building system controller and the building system comprises providing communication between the input/output module and a network interface of a piece of network technology equipment mounted in the network equipment rack in an enclosure distinct from the drawer enclosure.

In some embodiments, providing the communication link between the building system controller and the building system comprises providing communication between the input/output module and a cooling system configured to cool a room in which the network equipment rack is located.

In some embodiments, mounting the building system controller within the drawer enclosure comprises mounting the building system controller within the drawer enclosure at a location offsite from a building in which the network equipment rack is located.

In some embodiments, the method further comprises mounting one of an interruptible power supply and an automatic transfer switch on the network rack and electrically coupling a power outlet of the one of the interruptible power supply and the automatic transfer switch to a power input of the building management system power supply.

### BRIEF DESCRIPTION OF DRAWINGS

The accompanying drawings are not intended to be drawn to scale. In the drawings, each identical or nearly identical component that is illustrated in various figures is represented by a like numeral. For purposes of clarity, not every component may be labeled in every drawing. In the drawings:

FIG. 1 is an elevational view of a rack including embodiments of a BMS enclosure mounted thereon;

FIG. 2 is an isometric view of an embodiment of a portion of a BMS enclosure opened to illustrate the electronic components mounted therein;

FIG. 3 is an isometric view of an embodiment of a BMS enclosure; and

FIG. 4 illustrates a rear side of a rack including embodiments of a BMS enclosure mounted thereon.

### DETAILED DESCRIPTION

Aspects and embodiments disclosed herein are directed to methods and apparatus for providing components of a BMS in enclosures which are standardized and which may be mounted within industry standard mounting systems typically associated with information technology data center equipment. Aspects and embodiments disclosed herein provide for more easily installable and scalable BMS systems than previously known solutions and provide for a more standardized solution to building owner needs with respect to BMS implementations which may reduce the need for customized BMS solutions for individual building owners. The provision of standardized BMS component enclosures which are designed to fit into industry standard equipment mounting systems, which many building owners may already possess, may reduce the difficulties associated with installation, expansion, and servicing of BMS implementations.

In response to the increasing demands of information-based economies, information technology (IT) networks continue to proliferate across the globe. One manifestation of this growth is the centralized network data center. A centralized network data center typically includes various information technology equipment, collocated in a structure that provides network connectivity, electrical power, and cooling capacity. Often the equipment is housed in specialized enclosures termed “racks” which integrate these connectivity, power, and cooling elements.

A number of different standards have been developed to enable equipment manufacturers to design rack mountable equipment that can be mounted in racks manufactured by different manufacturers. One such standard is the Electronic Industries Alliance's EIA-310-D standard which defines parameters for what has become an industry standard 19 inch (48 cm) equipment rack. 19 inch equipment racks, as well as other equipment racks having standardized dimensions for mounting, for example, 23 inch (58 cm), 24 inch (61 cm), or 28 inch (71 cm) wide equipment, are used extensively in data centers and other facilities. With the proliferation of the Internet, it is not uncommon for a data center to contain hundreds of these equipment racks.

In some data center configurations, rows of equipment racks are organized into hot and cold aisles to facilitate cooling the information technology equipment. One or more cooling systems are typically provided in data centers to provide low temperature air for cooling the information technology equipment in the data center. These cooling systems may be controlled by controllers of a BMS. It has been discovered that numerous advantages may be achieved by mounting a BMS controller in a mounting system which may be fit into a standard data center rack, for example, a 19 inch rack, in a data center which is cooled by a system which the BMS system controller is configured to monitor and/or control.

In many data center construction projects wall space is a premium. Typical prior known BMS implementations may include panel enclosures for BMS equipment having dimensions of, for example, about 42 inches (107 cm) by 30 inches (76 cm) which covers much of that valuable wall space. A BMS rack mount solution as disclosed herein does not require wall space to implement and allows for flexibility in design and placement or BMS mounting solutions.

In some embodiments disclosed herein a BMS may be coupled to a computer workstation or other output device through which a user may access data associated with the system(s) controlled by the BMS. This data may be used to monitor trends in parameters such as power consumption of various building systems or to create charts and/or calculate statistics which may be analyzed for anomalies indicative of possible system faults or mis-settings and/or to determine if opportunities exist for improving the efficiency of the building system operations. In currently known BMS implementations, front end workstations cannot easily be installed with the BMS controllers. For example, a typical current BMS implementation design includes mounting BMS control electronics in a gray box hanging on a wall in a mechanical room which may not be an environment conducive to an operator working on a workstation associated with the BMS to perform analysis of the BMS performance.

Aspects and embodiment disclosed herein provide a more attractive BMS offering to data center clients by helping reduce construction time through offsite and/or concurrent construction of BMS component enclosures and the buildings and rooms in which the BMS component enclosures are to be placed. Further, aspects and embodiment disclosed herein provide more attractive BMS offering to data center clients by changing the perception that BMS is something to be installed in a mechanical room and not the white space or network room.

Embodiments of a BMS rack mount solution as disclosed herein may alleviate frustration experienced in the field by completing much of the BMS solution, for example, construction of a mounting enclosure for BMS components and mounting of the BMS components in the enclosure, offsite in a controlled environment. This may increase quality and consistency of the BMS implementation.

In addition, embodiments of a BMS rack mount solution as disclosed herein may include placing a BMS in a modular platform that can be easily scaled and manufactured with less need for customization than previously known solutions.

Embodiments of a BMS rack mount solution as disclosed herein allow for a modular approach to the designing of a BMS which may be provided in, for example, a data center environment. Also, the embodiments disclosed herein provide for the installation of BMS components in more flexible locations because of the use of modular enclosures which may be mounted in standard network racks.

In addition, embodiments of the BMS rack mount solution disclosed herein allow the BMS to provide enhanced functionality. For example, in some embodiments, a BMS controller may be mounted in a common enclosure along with power feed and network infrastructure devices.

The flexibility of embodiments of a BMS rack mount design disclosed herein allows for a constantly changing IT environment to include a BMS solution that changes with it. Embodiments of a BMS rack mount design disclosed herein provide for the end users of data centers to have influence over future solutions at their facilities and think of new ways to implement BMS solutions to best suit their needs.

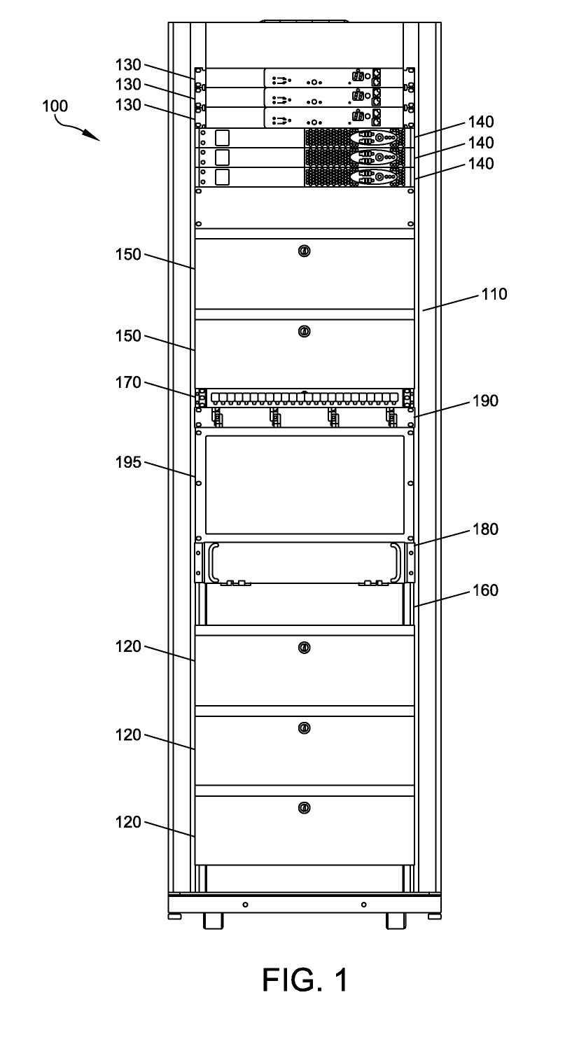

In some embodiments, the rack mounted BMS solution includes modular drawers that contain power and/or controller components of a BMS. An example of an embodiment of a rack mounted BMS solution, generally indicated at 100, is illustrated in FIG. 1. As shown in FIG. 1 a standard network equipment rack 110 may be fitted with one or more drawer enclosures 120 including BMS system electronics. In some embodiments, each drawer enclosure 120 may include two building system controllers and two input/output (I/O) modules configured to transfer data from a building system to a building system controller and to transfer commands from the building system controller to the building system. In some embodiments, the building system controllers include circuitry, for example, programmable logic controllers or other hard wired circuitry designed specifically for the control of building systems.

The drawer enclosures 120 may also include, for example, communication protocol adapters, such as RS 485 to Ethernet gateways, which would provide for electronics within the drawer which communicate using a protocol such as RS 485 to transmit and/or receive data through Ethernet connections. Additionally, the drawer enclosures 120 may also include one or more wireless data receivers configured to receive data from one or more building system sensors and communicate the received data to a building system controller in the drawer enclosure. The one or more wireless data receivers may include, for example, a wireless temperature monitor, which may be configured to receive data from a sensor in a portion of a room, for example, a hot or a cold aisle in a data center in which the drawer enclosure 120 is located.

Accompanying the drawer enclosures 120 are items that support power and/or network connections of the BMS controllers. Automatic transfer switches (ATSs) 130 and uninterruptible power supplies (UPSs) 140 can be installed as rack mounted devices to increase the power supply redundancy of the BMS. Power supply drawers 150, which in some embodiments may accommodate up to two power supplies each, may also be sized to be installed in the network equipment rack 110 to support the BMS controllers. Embodiments of the power supply drawers 150 may have similar or the same dimensions as embodiments the BMS component drawer enclosures 120. In some embodiments, one ATS 130 and one UPS 140 are provided for each power supply in the power supply drawers 150. As more controllers are needed, more power supply drawers 150 and BMS drawers 120 may be added. The network equipment rack 110 may also include other network technology equipment, for example, one or more servers 160, a patch panel 170, a keyboard tray 180, a cable organizer 190, and/or a monitor 195 or other user interface which may provide for an operator to communicate with the BMS controller(s). In some embodiments an input/output module disposed in a drawer enclosure 120 mounted in a network equipment rack may be in communication with a building system through a network interface of a piece of network technology equipment mounted in the network equipment rack in an enclosure distinct from the drawer enclosure 120.

In some embodiments, the drawer enclosure 120 comprises a 4 U (7 inch, 17.8 cm) high drawer including mounting fittings, for example, one or more female fittings for receiving a screw, bolt, or other fastener and/or one or more male fasteners such as screws or bolts, for mounting in a standard network rack enclosure. The drawer enclosures may have dimensions of, for example, about 19 inches (48 cm) in width by about 7 inches (17.8 cm) in height, by about 42 inches (107 cm) in depth, although dimensions of the drawer enclosure may be different in other embodiments. For example, embodiments of the drawer enclosure 120 may be sized to fit into a 24 inch (61 cm) or other sized network equipment rack. In some embodiments, the drawer enclosure 120 is formed from a material such as metal, for example, steel or aluminum, and in other embodiments may be formed from, or include portions formed from a plastic material, for example, polypropylene or polystyrene. Embodiments of the drawer enclosure 120 are not limited to any particular materials of construction. Embodiments of the drawer enclosure 120 may be provided with one or more air flow apertures which may provide for cooling air to enter the drawer enclosure and/or for hot air to exit, thus providing for cooling of equipment disposed within the drawer enclosure.

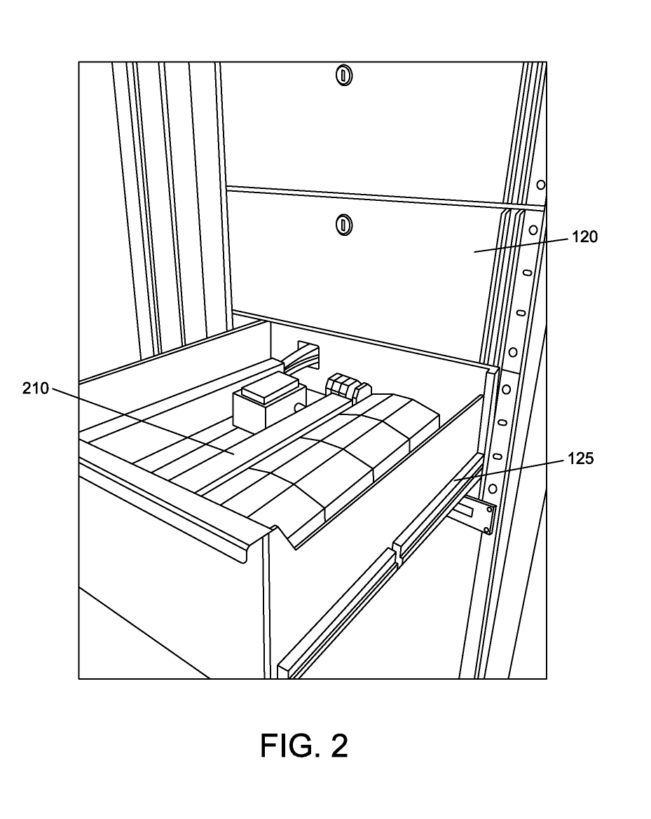

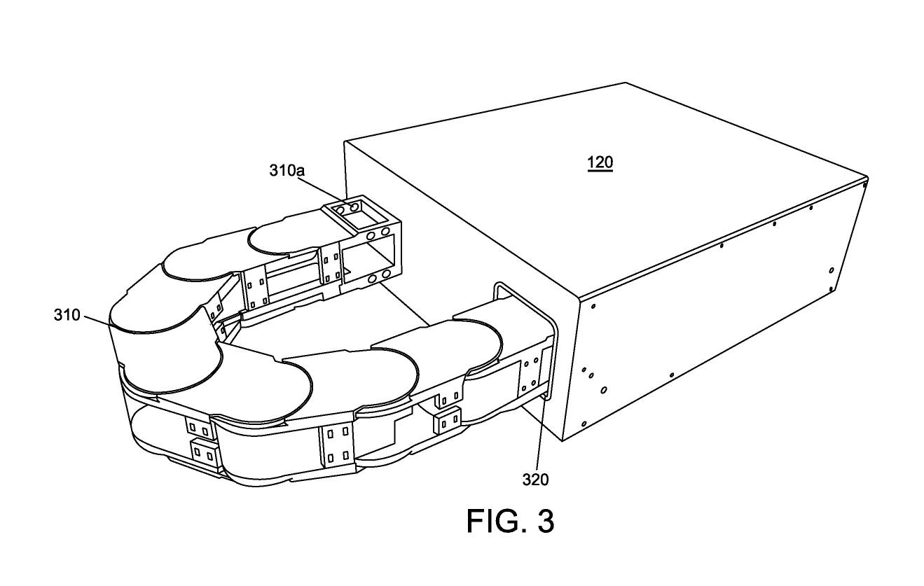

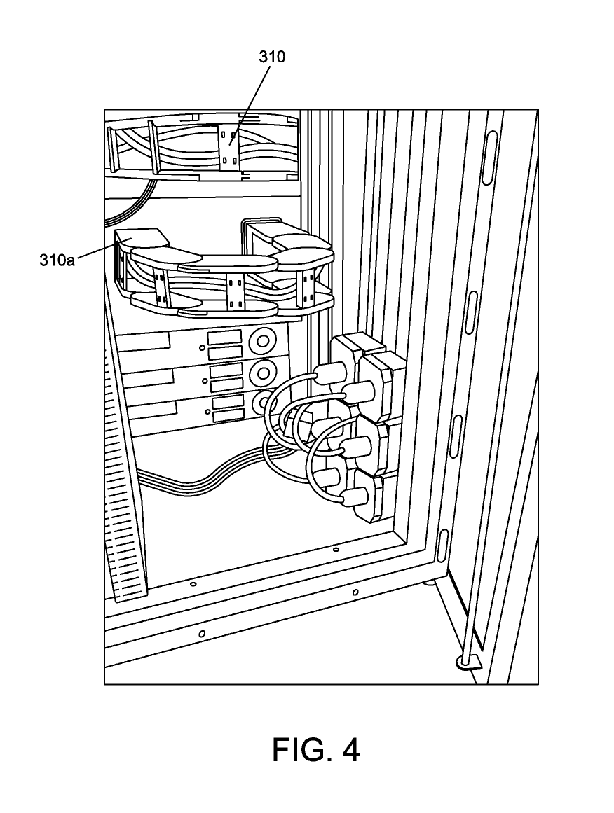

The drawer enclosures 120 may be opened along rails 125 to access the BMS components, for example, controller(s) and associated electronics 210 disposed within, as illustrated in FIG. 2. In some embodiments, as illustrated in FIGS. 3 and 4, the drawer enclosures 120 may be provided with a flexible raceway 310 for managing electrical cables associated with the BMS electronics. The flexible raceway 310 may have a first end 310a secured to a rear wall of the drawer enclosure and a second end secured to a movable internal portion of the drawer or to a board on which the BMS electronics may be mounted. The flexible raceway may move into and out of the drawer enclosure through an aperture 320 as the drawer is opened and closed.

The modular design of embodiments of the drawer enclosures 120 and associated BMS electronics 210 provides for construction of the system offsite of a location where the system will ultimately be installed. In some embodiments, upon installation, the controllers installed in rack mounted BMS solution may be connected directly to a BMS network through network connections already present in a data center in which the rack mounted BMS solution may be installed.

The BMS may be configured to monitor and control systems associated with the data center or other room in which it is installed. For example, the BMS may be configured to control lighting, cooling, access control, and/or fire control systems associated with a data center in which one or more of the BMS components are mounted. This may provide for operators to easily identify and locate a BMS controller for a particular system associated with the data center to obtain data regarding the performance of the system or to perform troubleshooting or upgrading of the BMS.

The rack mounted BMS solution moves BMS components from customized wall mounted enclosures into the server rack by uniquely organizing the components of a BMS solution. Power circuits and supporting components such as ATSs and UPSs may be combined to create a unique package of redundancy. Data center professionals will enjoy a solution that blends in with the rest of their IT equipment and seamlessly integrates with other systems required for day to day operation.

Aspects disclosed herein in accordance with the present embodiments, are not limited in their application to the details of construction and the arrangement of components set forth in the following description or illustrated in the drawings. These aspects are capable of assuming other embodiments and of being practiced or of being carried out in various ways. Examples of specific implementations are provided herein for illustrative purposes only and are not intended to be limiting. In particular, acts, elements and features discussed in connection with any one or more embodiments are not intended to be excluded from a similar role in any other embodiments.

Having thus described several aspects of at least one embodiment, it is to be appreciated various alterations, modifications, and improvements will readily occur to those skilled in the art. Such alterations, modifications, and improvements are intended to be part of this disclosure, and are intended to be within the spirit and scope of the disclosure. Accordingly, the foregoing description and drawings are by way of example only.

What is claimed is:

1. A building management system comprising:
a building system controller disposed within a drawer enclosure having dimensions providing for the drawer enclosure to be mounted in a network equipment rack having an industry standard configuration.

2. The building management system of claim 1, further comprising an input/output module disposed within the drawer enclosure, the input/output module configured to transfer data from a building system to the building system controller and to transfer commands from the building system controller to the building system.

3. The building management system of claim 2, wherein the drawer enclosure is mounted in the network equipment rack.

4. The building management system of claim 3, wherein the input/output module is in communication with the building system through a network interface of a piece of network technology equipment mounted in the network equipment rack in an enclosure distinct from the drawer enclosure.

5. The building management system of claim 4, further comprising a second building system controlled disposed within the drawer enclosure.

6. The building management system of claim 4, further comprising a second input/output module disposed within the drawer enclosure, the second input/output module configured to transfer data from a second building system to the second building system controller and to transfer commands from the second building system controller to the second building system.

7. The building management system of claim 3, further comprising a building management system power supply configured to provide power to the building system controller, the building management system power supply disposed in a power supply drawer mounted in the network equipment rack.

8. The building management system of claim 7, further comprising an uninterruptible power supply configured to provide power to the building management system power supply, the uninterruptible power supply mounted in the network equipment rack.

9. The building management system of claim 8, further comprising an automatic transfer switch configured to provide power to the building management system power supply, the automatic transfer switch mounted in the network equipment rack.

10. The building management system of claim 9, further comprising a front end workstation mounted in the network equipment rack, the front end workstation configured to record data provided by the building system controller and to perform analysis on the data.

11. The building management system of claim 10, wherein the drawer enclosure includes a flexible cable management raceway having a first end secured to a rear wall of the drawer enclosure and a second end secured to a movable internal portion of the drawer.

12. The building management system of claim 11, wherein the drawer enclosure includes one or more apertures defined in a wall of the drawer enclosure.

13. The building management system of claim 10, wherein the network equipment rack is disposed in an information technology data center including one or more building systems which the building system controller is configured to control and monitor.

14. The building management system of claim 13, wherein the one or more building systems are selected from the group consisting of a lighting system, a cooling system, an access control system, and a fire control system.

15. A method of assembling a building management system, the method comprising:
mounting a building system controller within a drawer enclosure having dimensions providing for the drawer enclosure to be mounted in a network equipment rack having industry standard dimensions;
mounting the drawer enclosure on the network equipment rack;
mounting a building management system power supply on the network equipment rack;
electrically coupling the building management system power supply to the building system controller; and
providing a communication link between the building system controller and a building system which the building system controller is configured to monitor and control.

16. The method of claim 15, wherein providing the communication link between the building system controller and the building system comprises providing communication between an input/output module disposed in the drawer enclosure, the building system controller, and the building system.

17. The method of claim 16, wherein providing the communication link between the building system controller and the building system comprises providing communication between the input/output module and a network interface of a piece of network technology equipment mounted in the network equipment rack in an enclosure distinct from the drawer enclosure.

18. The method of claim 16, wherein providing the communication link between the building system controller and the building system comprises providing communication between the input/output module and a cooling system configured to cool a room in which the network equipment rack is located.

19. The method of claim 15, wherein mounting the building system controller within the drawer enclosure comprises mounting the building system controller within the drawer enclosure at a location offsite from a building in which the network equipment rack is located.

20. The method of claim 15, further comprising mounting one of an interruptible power supply and an automatic transfer switch on the network rack and electrically coupling a power outlet of the one of the interruptible power supply and the automatic transfer switch to a power input of the building management system power supply.
